(19) United States
(12) Patent Application Publication
(10) Pub. No.: US 2023/0078510 A1
(43) Pub. Date: Mar. 16, 2023

(54) METHOD FOR FOCUSING AND OPERATING A PARTICLE BEAM MICROSCOPE

(71) Applicant: Carl Zeiss Microscopy GmbH, Jena (DE)

(72) Inventors: Simon Diemer, Lauchheim (DE); Björn Gamm, Koenigsbronn (DE)

(21) Appl. No.: 17/989,195

(22) Filed: Nov. 17, 2022

Related U.S. Application Data
(63) Continuation of application No. PCT/EP2021/063356, filed on May 19, 2021.

(30) Foreign Application Priority Data
May 19, 2020 (DE) 102020113502.5

(51) Int. Cl. H01J 37/28; H01J 37/04

(52) U.S. Cl. CPC H01J 37/28; H01J 37/04

(57) ABSTRACT

A method for operating a particle beam microscope comprises setting a distance of an object from an objective lens, setting an excitation of the objective lens, setting an excitation of a double deflector to a first setting such that a particle beam is incident on the object at a first orientation, and recording a first particle-microscopic image at these settings. The method also comprises setting the excitation of the double deflector to a second setting such that the particle beam is incident on the object at a second orientation which differs from the first orientation; and recording a second particle-microscopic image at the second setting of the double deflector. Thereupon, a new distance of the object from the objective lens is determined based on an analysis of the first and second particle-microscopic images, and the distance of the object from the objective lens is set to the new distance.

### CROSS-REFERENCE TO RELATED APPLICATIONS

The present application is a continuation of, and claims benefit under 35 USC 120 to, international application PCT/EP2021/063356, filed May 19, 2021, which claims benefit under 35 USC 119 of German Application No. 10 2020 113 502.5, filed May 19, 2020. The entire disclosure of these applications are incorporated by reference herein.

### FIELD

The present disclosure relates to methods for operating particle beam microscopes. For example, the disclosure relates to methods for operating those particle beam microscopes in which a particle beam or a plurality of particle beams are focused at an object to be examined. The disclosure further relates to a particle beam microscope for carrying out the method and to a computer program product for controlling such a particle beam microscope.

### BACKGROUND

An example of a particle beam microscope is a scanning electron microscope, in which a focused electron beam is scanned over an object to be examined and secondary electrons or backscattered electrons, generated by the incident electron beam at the object, are detected in a manner dependent on the deflection of the focused particle beam in order to generate an electron-microscopic image of the object.

The particle beam is generated by a particle beam source and accelerated; it possibly passes through a condenser lens and a stigmator and is focused at the object by an objective lens. In order to obtain a high spatial resolution of the particle beam microscope, the particle beam can be focused to the best possible extent at the object, i.e., a region illuminated by the focused particle beam at the surface of the object (“beam spot”) is desirably as small as possible. In practice, this is achieved by virtue of a user manually setting the focusing of the particle beam by operating actuating elements of the particle beam microscope and by the controller of the particle beam microscope changing the excitation of the objective lens or the excitation of the stigmator on the basis of the operation of the actuating elements. During this adjustment process, the particle beam is scanned continuously over the object in order to record images. The user can assess the quality of the current images and, in a manner dependent thereon, actuate the actuating elements until they are satisfied with the quality of the images or can no longer improve the quality thereof. However, this procedure can be time consuming and can place significant demands even on skilled users.

There are also automated methods, in which a suitable setting for parameters of the particle beam microscope is found automatically. In such methods, a plurality of recorded images are analysed with the aid of a computer in order to calculate on the basis of this analysis settings of the parameters that allow the recording of images which have an optimal image sharpness or have other quality criteria for images, such as a low value of an image astigmatism, for example. An example of such a method is described in US6838667B2. However, conventional automated methods which involve a small number of recorded images and hence are able to be performed within a relatively short period of time do not always supply the desired results.

Further information relating to the focusing of particle beams can be found in the following publications mentioned by way of example: US 2007/0120065A1, US 2013/0320210A1 and JP2007194060A.

### SUMMARY

The present disclosure proposes a method for operating a particle beam microscope which can simplify the focusing of the particle beam at an object to be examined and, for example, can be able to be performed in fast and reliable fashion.

According to embodiments of the disclosure, provision is made for a method for operating a particle beam microscope comprising a particle beam source for generating a particle beam, an objective lens for focusing the particle beam on an object, and a double deflector arranged in the beam path of the particle beam between the particle beam source and the objective lens, wherein the method comprises setting a distance of an object from the objective lens to a given distance and setting an excitation of the objective lens to a given excitation. Here, the given distance of the object from the objective lens can be selected according to a desired application, such as a magnification of the image to be generated and a landing energy of the particles of the particle beam on the object, for example. Then, the given excitation of the objective lens can be selected in such a way that, at the given distance and a given kinetic energy of the particles passing through the objective lens, a substantially sharp particle-microscopic image of the object can be generated using the particle beam microscope. However, this is usually only approximately possible in practice and it is desirable by repeatedly recording test images and analyzing them to find a changed setting of the excitation of the objective lens and/or to find a changed setting of the distance of the object from the objective lens at which a particle-microscopic image of the object that meets more stringent demands in respect of the image sharpness and other image qualities can be obtained.

According to embodiments, the method comprises setting an excitation of the double deflector to a first setting in such a way that the particle beam is incident on the object at a first orientation and obtaining first particle-microscopic data, for example recording a first particle-microscopic image or a first scan along a line, at the first setting of the double deflector. Thereupon, the method comprises setting the excitation of the double deflector to a second setting in such a way that the particle beam is incident on the object at a second orientation which differs from the first orientation, and obtaining second particle-microscopic data, for example recording a second particle-microscopic image or a second scan along a line, at the second setting of the double deflector.

The particle-microscopic data can be, for example, measured secondary particle intensities that are assigned to locations on the surface of the object. For example, the particle-microscopic data comprise a plurality of tuples, each representing a location on the object at which the particle beam was directed for a predetermined period of time, and an intensity of secondary particles detected while the particle beam was directed at the location. If the particle-microscopic data are particle-microscopic images, they represent, for example, measured secondary particle intensities that are assigned to a two-dimensionally extended region on the surface of the object. The intensities of secondary particles can be detected while the particle beam is scanned for example line by line over the two-dimensionally extended region, which can also be referred to as an image field, on the surface of the object. For example, when the particle-microscopic data are scans along a line, these represent measured secondary particle intensities assigned to points on the surface of the object that are located along a line. The intensities of secondary particles can be detected while the particle beam is scanned for example along a for example straight line having a starting point and an ending point on the surface of the obj ect.

According to exemplary embodiments, the line on the object is a straight line extending with a starting point and an ending point.

According to exemplary embodiments, the first and the second particle-microscopic data are obtained in such a way that they are each assigned to a multiplicity of locations of the object and that the locations assigned to the first particle-microscopic data and the locations assigned to the second particle-microscopic data have an intersection, that is to say, there are a plurality of locations on the object that are assigned to both the first particle-microscopic data and the second particle-microscopic data. If the first and second particle-microscopic data are particle-microscopic images, this means that the image fields of the first and of the second particle-microscopic image at least partially overlap. If the first and second particle-microscopic data are scans along a line, this means that the lines over which the particle beam is scanned to obtain the data at least partially overlap on the surface of the object or extend with only a slight spacing at a small angle to one another, that is to say almost parallel to one another.

According to embodiments, the method then further comprises determining a new distance of the object from the objective lens on the basis of an analysis of the first particle-microscopic data, such as the first particle-microscopic image or the first scan along a line, and the second particle-microscopic data, such as the second particle-microscopic image or the second scan along a line, setting the distance of the object from the objective lens to the new distance and obtaining third particle-microscopic data, such as recording a third particle-microscopic image, at the given excitation of the objective lens and at the new distance of the object from the objective lens. On the basis of the analysis of the first and the second particle-microscopic data, it is possible here to determine the new distance of the object from the objective lens in such a way that the third particle-microscopic data are obtained with a particle beam that is better focused at the surface of the object. If the third particle-microscopic data are the third particle-microscopic image, then this image is a comparatively sharper image of the surface of the object, wherein this image optionally also satisfies other possibly higher quality criteria. Here, the excitation of the objective lens is maintained after obtaining the first and the second particle-microscopic data, that is to say, the first, the second and the third particle-microscopic data are recorded at the same excitation of the objective lens while the distance of the object from the objective lens is changed in order to achieve better focusing of the particle beam at the surface of the object.

According to further embodiments, the method can then alternatively comprise determining a new excitation of the objective lens on the basis of an analysis of the first particle-microscopic data, such as the first particle-microscopic image or the first scan along a line, and the second particle-microscopic data, such as the second particle-microscopic image or the second scan along a line, setting the excitation of the objective lens to the new excitation, and obtaining third particle-microscopic data, such as recording the third particle-microscopic image, at the new excitation of the objective lens and at the given distance of the object from the objective lens. On the basis of the analysis of the first and the second particle-microscopic data, it is possible here to determine the new excitation of the objective lens in such a way that the third particle-microscopic data are obtained with a particle beam that is relatively well focused at the surface of the object. Here, the distance of the object from the objective lens is maintained after obtaining the first and the second particle-microscopic data, that is to say, the first, the second and the third particle-microscopic data are recorded at the same distance of the object from the objective lens while the excitation of the the objective lens is changed in order to achieve better focusing of the particle beam at the surface of the obj ect.

According to further embodiments, the method can then alternatively also comprise determining a new distance of the object from the objective lens and a new excitation of the objective lens on the basis of the analysis of the first particle-microscopic data, such as the first particle-microscopic image or the first scan along a line, and the second particle-microscopic data, such as the second particle-microscopic image or the second scan along a line, setting the distance of the object from the objective lens to the new distance, setting the excitation of the objective lens to the new excitation, and obtaining third particle-microscopic data, such as recording the third particle-microscopic image, at the new excitation of the objective lens and at the new distance of the object from the objective lens. On the basis of the analysis of the first and the second particle-microscopic data, it is possible here to determine the new distance of the object from the objective lens and the new excitation of the objective lens in such a way that the third particle-microscopic data are obtained with a particle beam that is relatively well focused at the surface of the object. In this case, after the first and the second particle-microscopic data have been obtained, both the excitation of the objective lens and the distance of the object from the objective lens are changed in order to obtain a sharper image. That is to say, the first and the second particle-microscopic data are recorded at the same excitation of the objective lens and at the same distance of the object from the objective lens, and the third particle-microscopic data, such as the third image, are obtained at a changed excitation of the objective lens and at a changed distance of the object from the objective lens.

The analysis can comprise a correlation of the first and the second particle-microscopic data.

According to exemplary embodiments, the method comprises setting an excitation of a stigmator arranged in the beam path of the particle beam between the particle beam source and the objective lens to a given setting, setting the excitation of the double deflector to a third setting in such a way that the particle beam is incident on the object at a third orientation which differs from the first orientation and from the second orientation, and obtaining fourth particle-microscopic data, such as a fourth particle-microscopic image or a fourth scan along a line, at the given setting of the stigmator. The method can then further comprise determining a new setting of the excitation of the stigmator on the basis of an analysis of the first particle-microscopic data, the second particle-microscopic data, and the fourth particle-microscopic data, such as the first particle-microscopic image, the second particle-microscopic image, and the fourth particle-microscopic image, or the first scan along a line, the second scan along a line, and the fourth scan along a line, and setting the excitation of the stigmator to the new excitation. Here, the first and the second particle-microscopic data are obtained at the given setting of the stigmator, and the third particle-microscopic data, such as the third particle-microscopic image, are recorded at the new setting of the excitation of the stigmator. The new setting of the excitation of the stigmator can be determined here in such a way that the focusing of the particle beam at the surface of the object has low astigmatism and thus the third particle-microscopic image that may have been recorded has not only a high image sharpness but also low astigmatism.

According to exemplary embodiments, the fourth particle-microscopic data are recorded here at the given excitation of the objective lens and at the given distance of the object from the objective lens.

According to exemplary embodiments, obtaining the second particle-microscopic data comprises scanning the particle beam along a first line on the surface of the object. Obtaining the third particle-microscopic data can then comprise scanning the particle beam along a second line on the surface of the object. In this case, a smallest angle between the first line and the second line can be greater than 20°, for example greater than 40°, such as greater than 80°.

According to further exemplary embodiments, the first and the second particle-microscopic data are recorded at the given excitation of the objective lens and at the given distance of the object from the objective lens.

According to exemplary embodiments, the first setting of the double deflector and the second setting of the double deflector are determined with the aim that substantially no or the smallest possible image offset occurs between the first particle-microscopic data and the fourth particle-microscopic data at the given setting of the distance of the object from the objective lens and the given excitation of the objective lens. If the particle beam is focused optimally on the surface of the object, the effective particle emitter is optically imaged onto the surface of the object through the objective lens, the possibly present condenser and other particle-optically effective elements in the beam path of the particle beam. Then, particle beams which emanate from the source at different angles land at the same location on the surface of the object at different angles.

Now, if no image offset occurs at the different orientations with which the particle beam is incident on the object when the first and the second particle-microscopic data are obtained, then this means that the excitation of the double deflector is chosen such that the particle beam appears to come directly from the particle emitter following the deflection by the double deflector. Further, if such settings of the double deflector are chosen and an image offset occurs between the first and the second particle-microscopic data, it is possible to deduce that it is desirable the given distance and/or the excitation of the objective lens are changed in order to obtain the third particle-optical data with relatively good focusing of the particle beam at the surface of the object or the relatively sharp third particle-microscopic image. In the process, it is possible, for example, to calculate on the basis of an ascertained image offset between the first and the second particle-microscopic data, such as between the first and the second particle-microscopic image, the desired change in the given excitation of the objective lens to the new excitation of the objective lens or the desired change in the given distance of the object from the objective lens to the new distance of the object from the objective lens.

The first, the second, and possibly the third setting of the double deflector can be determined on the basis of a computational model of the particle beam microscope. For example, this computational model contains a model of the relationship between the excitation of the objective lens and the distance of the object from the objective lens for various settings of other parameters of the particle beam microscope, such as, e.g., the high voltage used to accelerate the particle beam after its emergence from the particle beam source in order to obtain focused images.

The orientation with which the particle beam is incident on the object can be characterized by an azimuth angle and an elevation angle in relation to a principal axis of the objective lens. According to exemplary embodiments, the first orientation and the second orientation differ in relation to a principal axis of the objective lens with regard to their elevation angle. They can be the same with regard to their azimuth angle. According to exemplary embodiments, the second orientation and the third orientation differ in relation to a principal axis of the objective lens with regard to their azimuth angle and can in this case for example have the same elevation angle.

The computational model may further comprise a model of the relationship between an excitation of the deflection device for scanning the particle beam over the surface of the object and an orientation of the line along which the particle beam is scanned to obtain particle-optical data in the surface of the object. For example, this model takes into account a magnetic field of the objective lens and the resulting Larmor rotation of the particle beam.

The disclosure further comprises a computer program product comprising instructions that, upon execution by a controller of a particle beam microscope, cause the latter to carry out the above-described method.

### BRIEF DESCRIPTION OF THE DRAWINGS

Embodiments of the disclosure are explained in more detail below with reference to figures, in which:

FIG. 1 shows a schematic illustration of a particle beam microscope;

FIG. 2 shows a schematic illustration of a detail of a beam path in the particle beam microscope from FIG. 1;

FIG. 3 shows a flowchart for explaining a method for operating the particle beam microscope from FIG. 1;

FIG. 4 shows a flowchart for explaining a further method for operating the particle beam microscope from FIG. 1;

FIG. 5 shows a schematic illustration for explaining an image offset when the first and the second particle-microscopic data are particle-microscopic images; and

FIG. 6 shows a schematic illustration for explaining an image offset when the first and the second particle-microscopic data are scans along lines.

### DETAILED DESCRIPTION

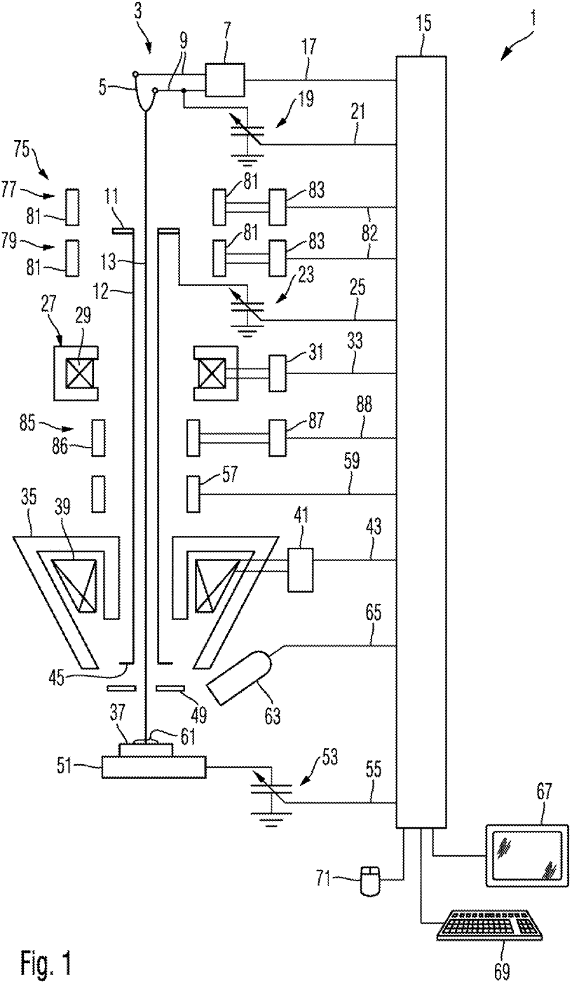

FIG. 1 is a schematic illustration of a particle beam microscope 1, which can be operated using a method according to embodiments of the disclosure. The particle beam microscope 1 comprises a particle beam source 3 comprising a particle emitter 5 and a driver 7. By way of example, the particle emitter 5 can be a cathode, heated by the driver 7 by way of lines 9, which emits electrons which are accelerated away from the particle emitter 5 by an anode 11 and shaped to form a particle beam 13. To this end, the driver 7 is controlled by a controller 15 of the particle beam microscope 1 by way of a control line 17, and an electrical potential of the particle emitter 5 is set by way of a settable voltage source 19, which is controlled by the controller 15 by way of a control line 21. An electrical potential of the anode 11 is set by way of a settable voltage source 23, which is likewise controlled by the controller 15 by way of a control line 25. A difference between the electrical potential of the particle emitter 5 and the electrical potential of the anode 11 defines the kinetic energy of the particles of the particle beam 13 after passing through the anode 11. The anode 11 forms the upper end of a beam tube 12, into which the particles of the particle beam 13 enter after passing through the anode 11.

The particle beam 13 passes through a condenser lens 27 which collimates the particle beam 13. In the illustrated example, the condenser lens 27 is a magnetic lens with a coil 29, which is excited by a current generated by a settable current source 31 controlled by the controller 15 by way of a control line 33.

The particle beam 13 thereupon passes through an objective lens 35, which is intended to focus the particle beam 13 at a surface of an object 37 to be examined. In the illustrated example, the objective lens 35 comprises a magnetic lens, the magnetic field of which is generated by a coil 39 which is excited by a current source 41 controlled by the controller 15 by way of a control line 43. The objective lens 35 further comprises an electrostatic lens, the electrostatic field of which is generated between a lower end 45 of the beam tube 12 and an electrode 49. The beam tube 12 is electrically connected to the anode 11, and the electrode 49 can be electrically connected to the ground potential or be set to a potential different from ground by way of a further voltage source (not illustrated in FIG. 1) controlled by the controller 15.

The object 37 is held at an object stage 51, the electrical potential of which is set by way of a voltage source 53 controlled by the controller 15 by way of a control line 55. The object 37 is electrically connected to the object stage 51 so that the object 37 also has the electrical potential of the object stage 51. A difference between the electrical potential of the particle emitter 5 and the electrical potential of the object 37 defines the kinetic energy of the particles of the beam 13 when incident on the object 37. In comparison therewith, the particles may have greater kinetic energy within the beam tube 12 and when passing through the condenser lens 27 and the objective lens 35 if they are decelerated by the electrostatic field between the end 45 of the beam tube 12 and the electrode 49 and/or by an electric field between the electrode 49 and the object 37.

However, it is also possible to embody the particle beam microscope 1 without beam tube 12 and electrode 49, and so the particles are decelerated or accelerated by an electric field between the anode 11 and the object 37 prior to being incident on the object 37. Independently of the embodiment of the particle beam microscope 1 with or without a beam tube 12 and independently of the embodiment and arrangement of the electrode 49, the kinetic energy of the particles when incident on the object 37 is dependent only on the difference between the potentials of the particle beam source 3 and of the object 37.

The particle beam microscope 1 furthermore comprises a deflection device 57 which is controlled by the controller 15 by way of a control line 59 and which deflects the particle beam 13 such that the particle beam 13 can scan a region 61 on the object 37 under control of the controller 15. The particle beam microscope 1 further comprises a detector 63, which is positioned in such a way that signals which are generated by the particle beam 13 directed at the object 37 and which leave the object are able to be incident on the detector 63 in order to be detected by the latter. These signals can comprise particles such as, for instance, backscattered electrons and secondary electrons or radiation such as, for instance, cathodoluminescence radiation.

In the particle beam microscope 1 illustrated in FIG. 1, the detector 63 is a detector arranged next to the objective lens 35 and in the vicinity of the object. However, it is also possible for the detector to be arranged in the beam tube 12 or at any other suitable position. For example if an electric field at the surface of the object has a decelerating effect on the incident electrons of the particle beam 13, secondary electrons leaving the object at low velocity are accelerated into the beam tube by this electric field and become detectable by a detector arranged in the beam tube 12 (not illustrated in FIG. 1).

The particles emanating from the object 37 are caused by the particle beam 13 being incident on the object 37. For example, these detected particles can be particles of the particle beam 13 itself, which are scattered or reflected at the object 37, such as, e.g., backscattered electrons, or they can be particles which are separated from the object 37 by the incident particle beam 13, such as e.g. secondary electrons. However, the detector 63 can also be embodied in such a way that it detects radiation, such as e.g. X-ray radiation, which is generated by the particle beam 13 incident on the object 37. Detection signals from the detector 63 are received by the controller 15 by way of a signal line 65. The controller 15 stores data, derived from the detection signals, depending on the current setting of the deflection device 57 during a scanning process, and so these data represent a particle beam-microscopic image of the region 61 of the object 37. This image can be presented by a display apparatus 67 connected to the controller 15 and be observed by a user of the particle beam microscope 1.

The particle beam microscope 1 further comprises a double deflector 75, which is arranged in the beam path of the particle beam 13 between the particle beam source 3 and the objective lens 35. In the example shown in FIG. 1, the double deflector 75 is arranged in the region of the anode 11; however, it could also be arranged between the particle beam source 3 and the anode 11, between the anode 11 and the condenser 27 or the objective lens 35, or between the condenser 27 and the objective lens 35. The double deflector 75 comprises two individual deflectors 77 and 79 which are arranged in succession in the beam path of the particle beam 13 and each have a plurality of deflection elements 81 arranged in distributed fashion in the circumferential direction around the particle beam 13. The deflection elements 81 can be formed by electrodes and/or coils, the excitation of which is provided by voltage or current sources 83, which are controlled by the controller 15 by way of lines 82. Each individual deflector 77, 79 of the double deflector 75 is configured to deflect, in a settable direction and through a settable angle, the particle beam 13 passing through the respective individual deflector. By way of example, if the deflection elements 81 of an individual deflector 77, 79 are electrodes, four electrodes arranged in distributed fashion in the circumferential direction around the particle beam 13 can be provided for this purpose, for example. By way of example, if the deflection elements 81 are coils, eight coils arranged in the circumferential direction around the particle beam 13 can be provided, for example.

The double deflector 75 can be used to adjust the particle beam 13; i.e., before the beam passes through the objective lens 35, it is aligned in such a way that the beam can be focused to the best possible extent at the object 37 by the objective lens 35. By way of example, the excitation of the double deflector 75 can be set in such a way that the particle beam 13 passes through a principal plane of the objective lens 35 along an optical axis in the objective lens 35. Further, the double deflector 75 can be used in a method for focusing the particle beam 13 at the object 37, as is described below.

The particle beam microscope 1 further comprises a stigmator 85, which comprises a plurality of stigmator elements 86 arranged in distributed fashion in the circumferential direction about the particle beam 13, the excitation of the stigmator elements being provided by a driver circuit 87, which is controlled by the controller 15 by way of a control line 88. The stigmator 85 is configured to provide an electric or magnetic quadrupole field, the magnitude and orientation of which are settable.

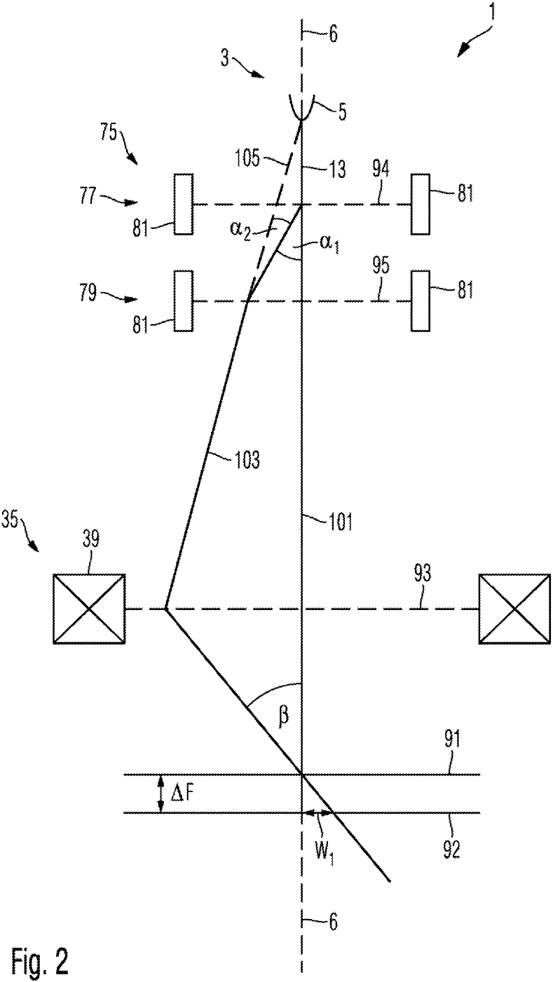

A method for focusing the particle beam microscope 1 is explained below with reference to FIG. 2. The latter shows a simplified schematic illustration of the beam path of the particle beam microscope 1. In the simplified illustration, the particle beam 13 generated by the particle beam source 3 is focused in a focal plane 91 by the objective lens 35. Apart from the objective lens 35, only the double deflector 75 acts on the particle beam. The effects of other particle-optical elements, such as, for instance, of the condenser 27, on the particle beam 13 are not illustrated in FIG. 2. However, the principles explained below are also applicable when taking account of the effects of other particle-optical elements. In the illustration of FIG. 2, the effects of the optical elements present occur in the principal planes thereof, where illustrated trajectories of the particle beam are “kinked.” Thus, the objective lens 35 has one principal plane 93, and the individual deflectors 77 and 79 of the double deflector 75 have principal planes 94 and 95, respectively. In fact, the effects of the particle-optical elements each extend over a larger region along the beam path of the particle beam 13.

The assumption is made that the particle beam 13 is focused in the focal plane 91 at a given excitation of the objective lens 35 and a given setting of the voltage applied to the anode 11 and the setting of the potential of the particle beam source 3. The distance of the focal plane 91 from the objective lens 35 can be calculated with a certain accuracy on the basis of these settings and a computational model of the particle beam microscope 1. Then, an attempt is made to arrange in the calculated focal plane 91 the surface of the object 37 to be examined. However, this is generally possible only with a limited accuracy. In the illustration of FIG. 2, the assumption is made that the surface of the object 37 to be examined is arranged in a plane 92 which has a distance ΔF from the focal plane 91. By way of example, in practice, it may be possible to position the surface of the object in the focal plane 91 with an accuracy of +/-500 µm.

If the surface of the object 37 is not arranged exactly in the focal plane 91, the generated particle-microscopic images exhibit unnecessary blurring. Thereupon, a method is started for focusing the particle beam microscope 1. To this end, for example, the distance of the object 37 from the objective lens 35 is changed in order to bring the plane 92, in which the surface of the object 37 is arranged, closer to the focal plane 91, or the excitation of the objective lens 35 is changed in order to bring the focal plane 91 closer to the plane 92, in which the surface of the object 37 is arranged. In order to determine a new distance of the object 37 from the objective lens 35 and/or a new excitation of the objective lens 35, used for this purpose, two or more particle-optical images are recorded at two or more different excitations of the double deflector 75 in the performed method.

FIG. 2 shows two possible excitations to this end by way of example. At the first excitation, the individual deflectors 77 and 79 of the double deflector 75 do not deflect the particle beam 13 at all, and so the latter runs along an optical axis 6 of the objective lens 75 along a solid line 3. At the second excitation of the double deflector 75, the particle beam runs along a solid line 103 in FIG. 2, wherein the first individual deflector 77 in FIG. 2 deflects the particle beam 13, which runs between the particle emitter 5 and the principle plane 94 of the individual deflector 77 on the optical axis 6, to the right by an angle α1 and the second individual deflector 79 then deflects the particle beam to the left by an angle α2. The angles α1 and α2 are determined in such a way that the particle beam 13 appears to come directly from the particle emitter 5 after passing through the second individual deflector 79, as illustrated by a dashed line 105 in FIG. 2.

Since the focal plane 92 of a particle beam microscope 1 is the plane into which the particle emitter 5 is imaged, the line 103 intersects the optical axis 6 in the focal plane 91. However, the line 103 intersects the plane 92, in which the surface of the object 37 is actually arranged, at a distance w1 from the optical axis 6.

A respective particle-microscopic image of the object is recorded in the two settings of the excitations of the double deflector 75, in which the particle beam 13 runs along the lines 101 and 103, respectively. These two images each show substantially the same structures of the surface of the object 37. However, there is an image offset, which corresponds to the distance w1, between the two recorded images. Therefore, the distance w1 can be determined from an analysis and a comparison of the two recorded particle-optical images. From the distance w1, it is then possible to determine the magnitude of the defocus, i.e., the distance ΔF between the focal plane 91 and the plane 92, in which the surface of the object is arranged, as a measure of the defocus of the particle beam at the surface of the object. It is evident from FIG. 2 that ΔF can be calculated, for example, if w1 is known and if the angle β between the line 103 and the optical axis 6 is known. This angle can be calculated on the basis of a computational model of the particle beam microscope 1 for the given excitation of the double deflector 75, which leads to the deflections of the particle beam by the angles α1 and α2. The data for this computational model can be determined in advance by simulation or experiment.

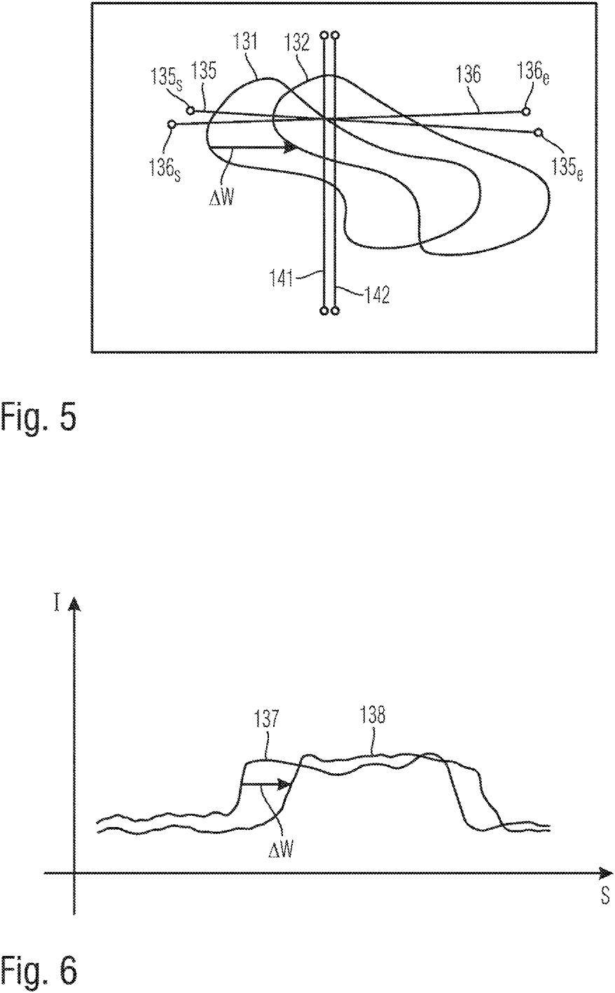

The determination of the distance w1 from the analysis of the two images will now be explained with reference to FIG. 5. FIG. 5 shows the first image recorded at the first setting of the excitation of the double deflector 75, superimposed on the second image recorded at the second setting of the excitation of the double deflector 75. Reference sign 131 in FIG. 5 denotes the outline of a structure which is present on the object and becomes visible in the first particle-microscopic image. The outline of the structure 131 of the first image is denoted by the reference sign 132 in FIG. 5, as it becomes visible in the second particle-microscopic image. By analyzing the two images, for example by correlating them using a Fourier transform, the offset between the two images, which corresponds to the distance w1 represented by an arrow w1 in FIG. 5, can be determined.

In FIG. 2, the particle beam 103 is incident on the surface of the object at an orientation which can be characterized by an azimuth angle and an elevation angle in relation to a principal axis of the objective lens 35. The elevation angle is the angle 90°-β, and the azimuth angle is the angle at which the plane of the drawing of FIG. 2 is oriented to the principal axis of the objective lens 35.

On the basis of the calculated value of ΔF, it is then possible to determine the new distance of the object 37 from the objective lens 35 at which a sharp particle-microscopic image of the object can be recorded at an unchanged excitation of the objective lens 35, or it is possible to determine the new excitation of the objective lens 35 at which a sharp particle-microscopic image of the object 37 can be recorded at an unchanged distance of the object 37 from the objective lens 35, or it is possible to determine a new distance of the object from the objective lens and a new excitation of the objective lens at which it is likewise possible to record a sharp particle-microscopic image of the object.

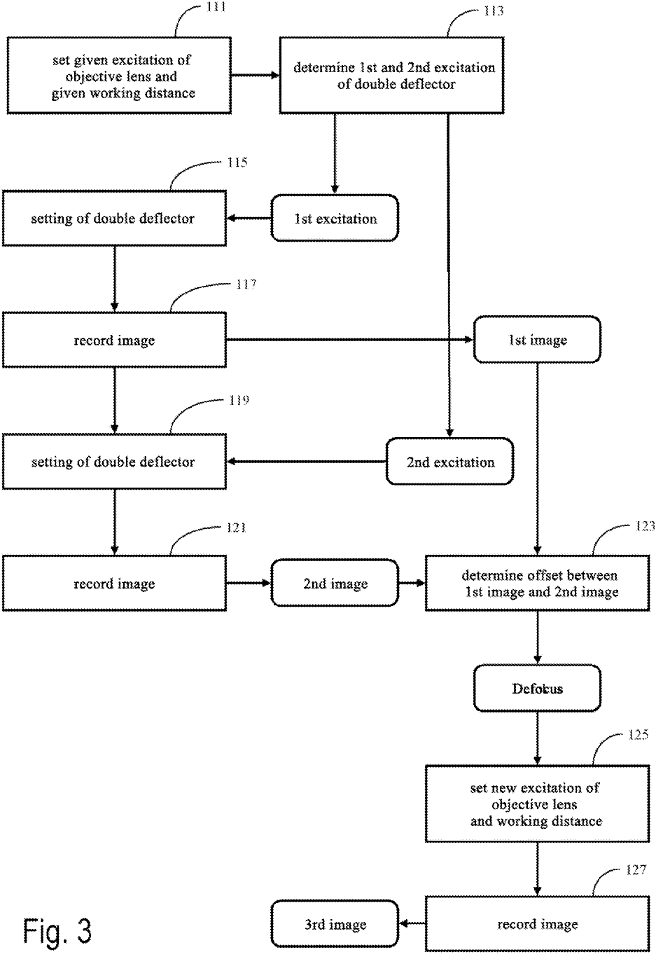

The method for focusing the particle beam microscope 1 is explained again below with reference to the flowchart in FIG. 3. In the method, a given excitation of the objective lens and a given working distance, which is the distance between the object and the objective lens, are determined first in a step 111 with the aim of being able to generate a particle-microscopic image of the object that is as sharp as possible at these settings and with the aim of an offset between the two subsequently recorded particle-microscopic images being equal to zero. The objective lens is excited and the object is positioned relative to the particle beam microscope in accordance with these settings.

Then, two different excitations of the double deflector are determined in a step 113. By way of example, determining each excitation of the double deflector includes the determination of two deflection angles by which the two individual deflectors deflect the particle beam and which are dimensioned in such a way that the particle beam appears to come from the particle emitter 5 after passing through the double deflector. Then, the first excitation of the double deflector is set in a step 115, whereupon a first particle-microscopic image of the object is recorded in a step 117. Thereupon, the second excitation of the double deflector is set in a step 119, and a second particle-microscopic image is recorded in a step 121. The two recorded particle-microscopic images are analyzed in a step 123 and an image offset between these two images is determined. The defocus ΔF is then further determined in step 123 from the determined image offset and with the additional help of a computational model of the particle beam microscope. Then, a new excitation of the objective lens and/or a new distance of the object from the objective lens are set in a step 125 on the basis of the defocus ΔF. Thereupon, one or more sharp particle-microscopic images of the object can be recorded in a step 127.

In the example explained with reference to FIG. 2, the first excitation of the double deflector 75 is chosen in such a way that the two individual deflectors 77 and 79 respectively do not deflect the particle beam 13 and the latter runs along the line 101 on the optical axis 6 of the objective lens 35. The second setting of the double deflector 75 is chosen in such a way that the two individual deflectors 77 and 79 deflect the particle beam 13 by the angles α1 and α2, respectively, in the plane of the drawing of FIG. 2 such that the particle beam runs along the line 103 in the plane of the drawing of FIG. 2 and is incident on the surface of the object 37 at the elevation angle 90°-β and at the azimuth angle that corresponds to the plane of the drawing. The two particle-microscopic images recorded at the two settings of the double deflector 75 have an image offset w1, which likewise lies in the plane of the drawing of FIG. 2 and which is directed to the right, for example, in FIG. 2 and, for example, can define an x-direction.

It is then possible to implement a third setting of the excitation of the double deflector 75 at which the particle beam 13 is once again deflected by angles α1 and α2 by the individual deflectors 77 and 79, but wherein these deflections are oriented in such a way that they lie in a plane which is oriented orthogonally to the plane of the drawing of FIG. 2 and contains the optical axis 6 of the objective lens 35. This corresponds to an azimuth angle that differs from that of the second setting by 90°. A further image of the object 37 can be recorded at this third setting of the excitation of the double deflector 75. By comparing this further image with the first image, it is in turn possible to determine an image offset w2, which is oriented in a direction which is oriented orthogonally to the plane of the drawing of FIG. 2 and can define a y-direction, for example.

If the imaging of the particle emitter 5 into the focal plane 91 is astigmatism-free, the two image offsets w1 and w2, measured in the x-direction and y-direction, respectively, will have the same absolute values. Conversely, if the image offset in the x-direction w1 and the image offset in the y-direction w2 have different absolute values, a corresponding defocus ΔFx in the x-direction can be assigned to the image offset in the x-direction and a corresponding defocus ΔFy in the y-direction can be assigned to the image offset in the y-direction. An astigmatism of the imaging of the particle emitter 5 into the focal plane 91 can be determined from the difference between the defocus ΔFx in the x-direction and the defocus ΔFy in the y-direction. Then, an excitation of the stigmator 85 can be changed on the basis of this determined value of the astigmatism in order to compensate for the astigmatism. Consequently, besides determining the defocus ΔF and subsequently improving the focusing of the particle beam microscope, it is also possible to determine the astigmatism and thereafter to compensate for the latter.

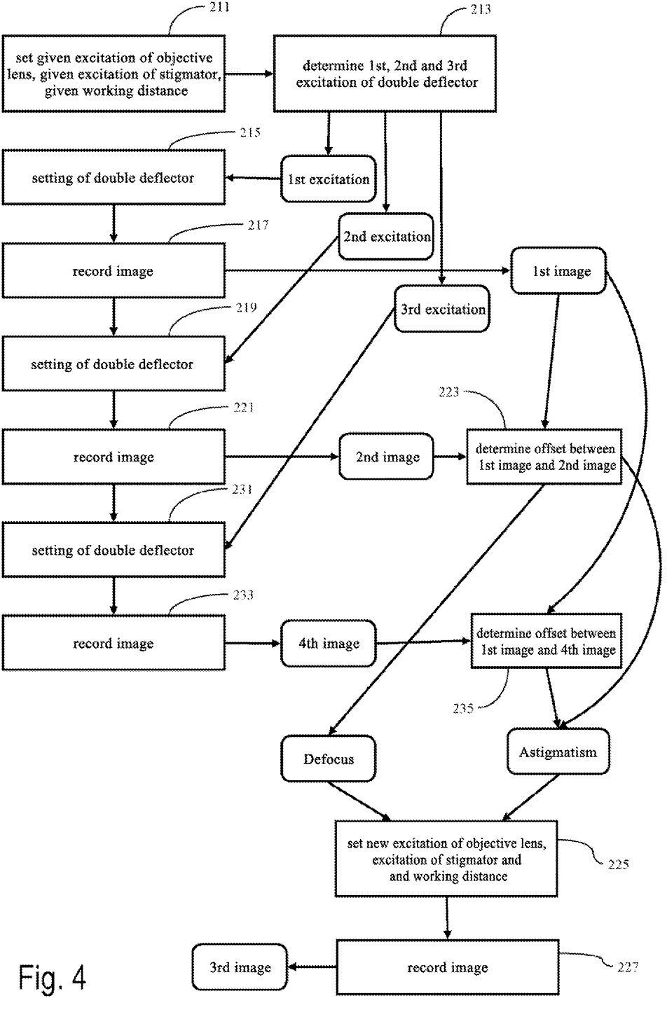

This method is explained again below with reference to the flowchart in FIG. 4. A given excitation of the objective lens, a given excitation of the stigmator, and a given working distance are set in a step 211. These settings are implemented with the aim of being able to obtain particle-microscopic images of the object that are as sharp as possible. Three different excitations of the double deflector are determined in a step 213. The first excitation of the double deflector is set in a step 215, whereupon a first particle-microscopic image of the object is recorded in a step 217. Thereafter, the second excitation of the double deflector is set in a step 219, and a second particle-microscopic image of the object is recorded in a step 221. Thereupon, the third excitation of the double deflector is set in a step 231, and a fourth particle-microscopic image is recorded in a step 233.

The offset between the first image and the second image is determined in a step 223 and the defocus ΔF is determined therefrom. The offset between the first and the third image is determined in a step 235, and this offset is compared with the offset between the first image and the second image in order to determine an astigmatism therefrom. Then, a new excitation of the stigmator and a new excitation of the objective lens and/or a new working distance are determined and set in a step 225 such that one or more sharp particle-microscopic images of the object can be recorded in a step 227.

These images can be presented on a screen 76 of the particle beam microscope 1. The user of the particle beam microscope 1 can control the latter and, for example, the start of the focusing method by way of operating elements, for instance a keyboard 69 and a mouse 71, and a user interface, which is displayed on the screen.

In the examples explained with reference to FIGS. 3, 4 and 5, the particle-microscopic data obtained at different settings of the excitation of the double deflector are particle-microscopic images. Embodiments in which the particle-microscopic data obtained at different settings of the excitation of the double deflector are scans along a line will now explained.

For this purpose, the particle beam 13 is moved along a line 135 on the surface of the object 37 at the first setting of the excitation of the double deflector 75 by actuating the deflection device 57. The line 135 extends along a straight line and has a starting point 135ₛ and an ending point 135ₑ. While the particle beam is scanned from the starting point 135ₛ along the line 135 to the ending point 135ₑ, the intensity of secondary particles detected with, for example, the detector 63 is recorded. The result is shown in the graph of FIG. 6, where the detected intensity I is plotted against the distance s on the surface of the object 37. A curve 137 shows the intensities recorded when scanning along line 135 at the first setting of the excitation of the double deflector 75.

At the second setting of the excitation of the double deflector 75, the particle beam 13 is scanned along a line 136 with a starting point 136ₛ and an ending point 136ₑ on the surface of the object 37. The line 136 is chosen to coincide with or be close to the line 135 on the object. For example, the two lines 135 and 136 extend at a small distance from one another and at a small angle to one another, so that they extend almost parallel to one another. For example, the maximum distance between the two lines 135 and 136 on the object 37 is less than a few tens of nanometers. A curve 138 shows the intensities recorded when scanning along the line 136 at the second setting of the excitation of the double deflector 75.

The offset w1 can be determined from the comparison of the two curves 137 and 138. In comparison with the determination of the offset from two images, for the recording of which the particle beam is scanned over a two-dimensionally extended region, the offset can be determined much more quickly from the scans along a line.

For this it is desirable that the orientation of the lines 135 and 136 on the surface of the object 37 is suitably selected. The orientation can be chosen such that the difference between the first and the second orientation with which the particle beam 13 is incident on the surface of the object at the first and second settings of the double deflector 75 causes a maximum offset w1 between the curves 137 and 138. For this purpose, the orientation of the two lines 135 and 136 is determined using a computational model of the particle beam microscope 1. The computational model takes into account here for example the azimuth angles of the first orientation and the second orientation with which the particle beam 13 is incident on the surface of the object 37 at the first and second settings of the double deflector 75. In order to excite the deflection device 57 in such a way that the scans are carried out along the lines 135 and 136, for example the Larmor rotation of the particle beam 13 in the magnetic field of the objective lens 35 is taken into account. However, it is also possible to determine the two orientations with which the particle beam 13 is incident on the surface of the object 37 at the first and second settings of the double deflector 75 in a corresponding manner, based on the previously specified orientation of the lines 135 and 136 on the object.

The method according to FIG. 3, which in step 123 determines the offset w1 by comparing the first image and the second image, can be modified by not recording the first image in step 117 with the first setting of the excitation of the double deflector 75, but performing a first scan along the line 135 in FIG. 5. Then, in step 121, the second image is not recorded with the second setting of the excitation of the double deflector 75, but a second scan is performed along the line 136 in FIG. 5. In step 123, the offset w1 is then determined from the data relating to the scans along the line 135 and the data relating to the scans along the line 136 in order to determine the defocus ΔF therefrom. Then, a new excitation of the objective lens and/or a new distance is set in step 125.

The method according to FIG. 4, which in steps 223 and 235 determines a respective offset by comparing the first image and the second image, and the first image and the fourth image, respectively, can be modified similarly to use scans along lines rather than using images and still be able to determine the defocus and astigmatism.

For this purpose, in step 217, the first image is not recorded but rather a scan along the line 135, which is oriented in the x-direction, and a scan along a line 141, which is oriented at an angle to the line 135, are performed at the first setting of the double deflector 75. In the example of FIG. 5, the line 141 is oriented at approximately 90° to the line 135, i.e. in the y-direction. A scan along the line 136 is then performed in step 221 at the second setting of the double deflector 75. From the comparison of the data from the scan along the line 135 and the data from the scan along the line 136, an offset can be determined in step 223, which corresponds to a defocus ΔFx, since the lines 135 and 136 are oriented in the x-direction. Then, in step 233, at the third setting of the double deflector 75, a scan is performed along a line 142 which overlaps with the line 141 or is only slightly spaced apart from it. From the comparison of the data from the scan along the line 141 and the data from the scan along the line 142, an offset can be determined in step 235, which corresponds to a defocus ΔFy, since the lines 141 and 142 are oriented in the y-direction. A defocus ΔF can then be determined from ΔFx and ΔFy, for example by averaging ΔFx and ΔFy, and an astigmatism can be determined, in order to determine therefrom and set a new excitation of the objective lens 35, a new excitation of the stigmator 85, and/or a new working distance in step 225, in order then to record an image with improved image sharpness and less astigmatism in step 227.

The particle beam device is an electron microscope in the above-described embodiments. However, the disclosure is also applicable to other particle beam devices. Examples thereof include: an ion beam device and a combination of an ion beam device and an electron beam device, in which a location on an object can be irradiated both by an ion beam generated by the ion beam device and by one generated by the electron beam device. Further, the particle beam device can also be a multibeam particle beam device, in which a plurality of particle beams are directed in parallel next to one another at an obj ect.

What is claimed is:

1. A method for operating a particle beam microscope, the particle beam microscope comprising a particle beam source configured to generate a particle beam an objective lens configured to focus the particle beam on an object, and a double deflector a beam path of the particle beam between the particle beam source and the objective lens, the method comprising:
when an object is set to a first distance from the objective lens, the objective lens is set to a first excitation, and the double deflector is set to a first excitation so that the particle beam is incident on the object at a first orientation, obtaining first particle-microscopic data at the first setting of the double deflector;
setting the excitation of the double deflector to a second setting so that the particle beam is incident on the object at a second orientation different from the first orientation;
obtaining second particle-microscopic data at the second setting of the double deflector; and
based on an analysis of the first and second particle-microscopic data, performing at least one of the following:
i) determining a second distance of the object from the objective lens, and setting the distance of the object from the objective lens to the second distance; and
ii) determining a second excitation of the objective lens, and setting the excitation of the objective lens to second new excitation.

2. The method of claim 1, wherein the first particle-microscopic data comprise a first particle-microscopic image, and the second particle-microscopic data comprise a second particle-microscopic image.

3. The method of claim 1, wherein the particle beam microscope further comprises a deflection device configured to scan the particle beam over a surface of the object, and obtaining the first and the second particle-microscopic data each comprises scanning the particle beam over a two-dimensionally extended region on the surface of the object.

4. The method of claim 1, wherein the particle beam microscope further comprises a deflection device configured to scan the particle beam over a surface of the object, and obtaining the first and the second particle-microscopic data each comprises scanning the particle beam along a line on the surface of the object.

5. The method of claim 4, further comprising at least one of the following:
determining an orientation of the line in the surface of the object based on an azimuth angle of the orientation with which the particle beam is incident on the object; and
determining the azimuth angle of the orientation with which the particle beam is incident on the object based on the orientation of the line in the surface of the object.

6. The method of claim 1, wherein the first and second settings of the double deflector are determined so that substantially no image offset occurs between the first and the second particle-microscopic data.

7. The method of claim 6, wherein the first and second settings of the double deflector are determined on the basis of a computational model of the particle beam microscope.

8. The method of claim 1, wherein the first orientation differs from the second orientation by at least 0.01°.

9. The method of claim 1, wherein, relative to a principal axis of the objective lens, the first and second orientations differ with regard to their elevation and are the same with regard to their azimuth.

10. The method of claim 1, further comprising one of the following:
obtaining third particle-microscopic data at the first excitation of the objective lens and at the second distance of the object from the objective lens;
obtaining third particle-microscopic data at the second excitation of the objective lens and at the first distance of the object from the objective lens; and
obtaining third particle-microscopic data at the second excitation of the objective lens and at the second distance of the object from the objective lens.

11. The method of claim 10, wherein the third particle-microscopic data comprise a third particle-microscopic image.

12. The method of claim 11, wherein the first, second and third settings of the double deflector are determined based on a computational model of the particle beam microscope.

13. The method of claim 1, wherein the particle beam microscope further comprises a stigmator in the beam path of the particle beam between the particle beam source and the objective lens, and the method further comprises:
setting an excitation of the stigmator to a first setting;
setting the excitation of the double deflector to a third setting so that the particle beam is incident on the object at a third orientation which differs from both the first and second orientations;
obtaining fourth particle-microscopic data at the given setting of the stigmator;
determining a second setting of the excitation of the stigmator based on an analysis of the first, second and fourth particle-microscopic data; and
setting the excitation of the stigmator to the second excitation,
wherein the first and the second particle-microscopic data are obtained at the first setting of the stigmator, and the third particle-microscopic data are obtained at the second setting of the excitation of the stigmator.

14. The method of claim 13, wherein the fourth particle-microscopic data are obtained at the first excitation of the objective lens and at the first distance of the object from the objective lens.

15. The method of claim 13, wherein the first, the second and the third settings of the double deflector are determined so that no image offset occurs between the first and fourth particle-microscopic data at the first of the distance of the object from the objective lens and the first excitation of the objective lens.

16. The method of claim 13, wherein, relative to a principal axis of the objective lens, the second and third orientations differ with regard to their azimuth.

17. The method of claim 13, wherein, relative to a principal axis of the objective lens, the second and third orientations are the same with regard to their elevation.

18. The method of claim 13, wherein:
obtaining the second particle-microscopic data comprises scanning the particle beam along a first line on the surface of the object;
obtaining the third particle-microscopic data comprises scanning the particle beam along a second line on the surface of the object; and
a smallest angle between the first and second lines is greater than 10°.

19. The method of claim 1, wherein the first and second particle-microscopic data are recorded at the first excitation of the objective lens and at the first distance of the object from the objective lens.

20. The method of claim 1, wherein the double deflector comprises two individual deflectors at a distance from each other in the beam path of the particle beam.

21. The method of claim 1, wherein the individual deflector comprises four or eight deflection elements distributed in a circumferential direction around the particle beam.

22. The method of claim 21, wherein the deflection elements comprise electrodes and/or coils.

23. One or more machine-readable hardware storage devices comprising instructions that are executable by one or more processing devices to perform operations comprising the method of claim 1.

24. A system comprising:
one or more processing devices; and
one or more machine-readable hardware storage devices comprising instructions that are executable by the one or more processing devices to perform operations comprising the method of claim 1.
